(19) United States
(12) Patent Application Publication
(10) Pub. No.: US 2013/0224922 A1
(43) Pub. Date: Aug. 29, 2013

(54) UMOS Semiconductor Devices Formed by Low Temperature Processing

(71) Applicant: Fairchild Semiconductor Corporation, (US)

(72) Inventor: Robert J. Purtell, West Jordan, UT (US)

(73) Assignee: Fairchild Semiconductor Corporation, San Jose, CA (US)

(21) Appl. No.: 13/865,741

(22) Filed: Apr. 18, 2013

Related U.S. Application Data
(63) Continuation of application No. 12/894,546, filed on Sep. 30, 2010.

(51) Int. Cl. H01L 29/66

(52) U.S. Cl. CPC H01L 29/66666
USPC 438/270

(57) ABSTRACT

UMOS (U-shaped trench MOSFET) semiconductor devices that have been formed using low temperature processes are described. The source region of the UMOS structure can be formed before the etch processes that are used to create the trench, allowing low-temperature materials to be incorporated into the semiconductor device from the creation of the gate oxide layer oxidation forward. Thus, the source drive-in and activation processing that are typically performed after the trench etch can be eliminated. The resulting UMOS structures contain a trench structure with both a gate insulting layer comprising a low temperature dielectric material and a gate conductor comprising a low temperature conductive material. Forming the source region before the trench etch can reduce the problems resulting from high temperature processes, and can reduce auto doping, improve threshold voltage control, reduce void creation, and enable incorporation of materials such as silicides that cannot survive high temperature processing. Other embodiments are described.

### FIELD

This application relates generally to semiconductor devices and methods for making such devices. More specifically, this application describes UMOS semiconductor devices that have been formed using low temperature processes.

### BACKGROUND

Semiconductor devices containing integrated circuits (ICs) or discrete devices are used in a wide variety of electronic apparatus containing a circuit board. The IC devices (or chips, or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning. Silicon wafers are typically used as the substrate and photolithography is used to mark different areas of the substrate to be doped or to deposit and define polysilicon, insulators, or metal layers.

One type of semiconductor device, a metal oxide silicon field effect transistor (MOSFET) device, can be widely used in numerous electronic apparatus, including automotive electronics, disk drives and power supplies. Generally, these devices function as switches, and they are used to connect a power supply to a load. Some MOSFET devices can be formed in a trench that has been created in a substrate. One feature making the trench configuration attractive is that the current flows vertically through the channel of the MOSFET. This permits a higher cell and/or current channel densities than other MOSFETs where the current flows horizontally through the channel and then vertically through the drain. Greater cell and/or current channel densities generally mean more MOSFETs and/or current channels can be manufactured per unit area of the substrate, thereby increasing the current density of the semiconductor device containing the trench MOSFET.

### SUMMARY

This application describes UMOS (U-shaped trench MOSFET) semiconductor devices that have been formed using low temperature processes. The source region of the UMOS structure can be formed before the etch processes that are used to create the trench, allowing low-temperature materials to be incorporated into the semiconductor device from the creation of the gate oxide layer oxidation forward. Thus, the source drive-in and activation processing that are typically performed after the trench etch can be eliminated. The resulting UMOS structures contain a trench structure with both a gate insulting layer comprising a low temperature dielectric material and a gate conductor comprising a low temperature conductive material. Forming the source region before the trench etch can reduce the problems resulting from high temperature processes, and can reduce auto doping, improve threshold voltage control, reduce void creation, and enable incorporation of materials such as silicides that cannot survive high temperature processing.

### BRIEF DESCRIPTION OF THE DRAWINGS

The following description can be better understood in light of the Figures, in which:

FIG. 1 shows some embodiments of UMOS semiconductor devices;

FIG. 2 depicts some embodiments of methods for making a semiconductor structure containing epitaxial layers;

FIG. 3 shows some embodiments of methods for making a semiconductor structure with a gate structure formed in a trench;

FIG. 4 depicts some embodiments of methods for making a semiconductor structure with a source layer and drain layer;

FIG. 5 depicts other embodiments of methods for making a semiconductor structure containing epitaxial layers;

FIG. 6 depicts other embodiments of methods for making a semiconductor structure containing epitaxial layers;

FIG. 7 depicts other embodiments of methods for making a semiconductor structure containing epitaxial layers;

FIG. 8 depicts other embodiments of methods for making a semiconductor structure containing epitaxial layers;

FIG. 9 depicts other embodiments of methods for making a semiconductor structure containing epitaxial layers;

FIG. 10 depicts other embodiments of methods for making a semiconductor structure containing epitaxial layers;

FIG. 11 depicts other embodiments of methods for making a semiconductor structure containing epitaxial layers;

FIG. 12 shows other embodiments of methods for making a semiconductor structure with a gate structure formed in a trench; and

FIG. 13 shows other embodiments of methods for making a semiconductor structure with the gate structure in the trench and a well region.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while description refers to UMOS (U-shaped trench MOSFET) semiconductor devices, it could be modified for other semiconductor devices formed in trenches, such as Static Induction Transistor (SIT), Static Induction Thyristor (SITh), JFET, thyristor devices, and LDMOS devices.

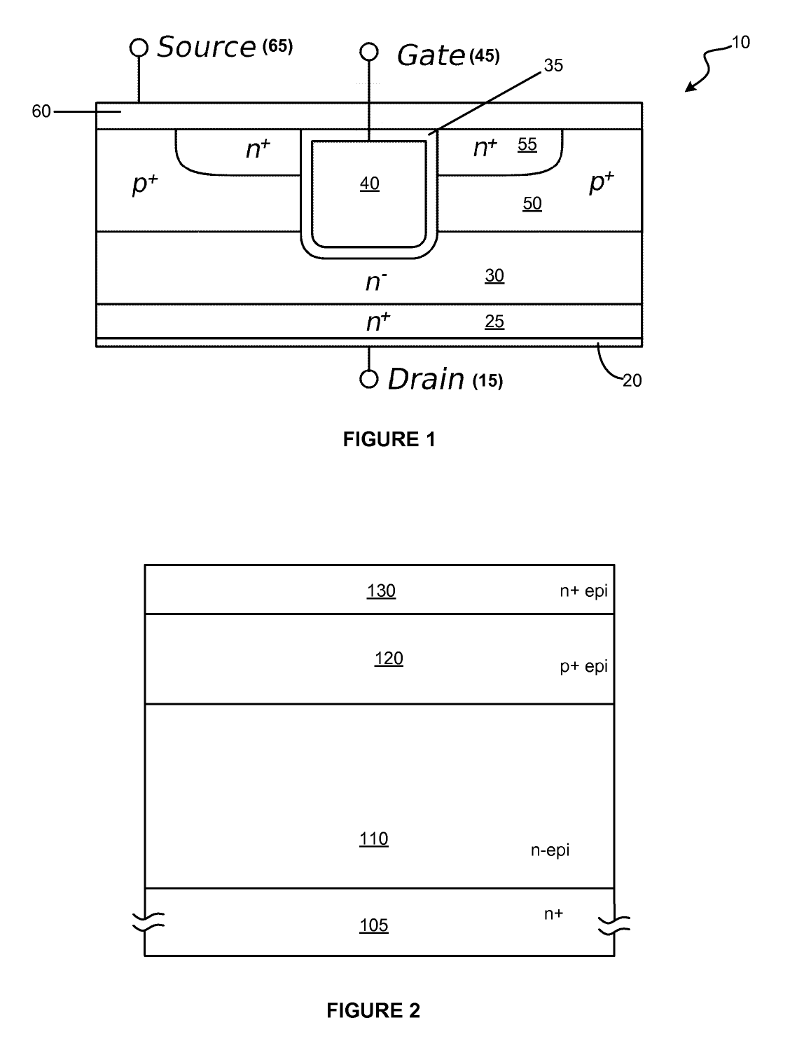

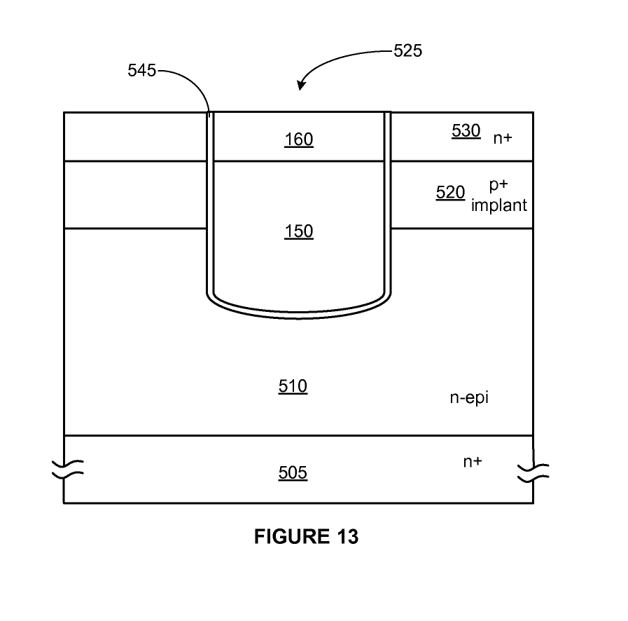

Some embodiments of the semiconductor devices and methods for making such devices are shown in FIGS. 1-13. FIG. 1 shows a UMOS (U-shaped trench MOSFET) structure that has been formed using low temperature processing. The UMOS structure 10 contains a drain metal layer 15 that is connected to a drain 20. The UMOS structure 10 also contains a substrate 25 that have been heavily doped with an n-type dopant. An epitaxial layer 30 has been formed on the substrate 25 and has been lightly doped with an n-type dopant. A trench has been formed in the epitaxial layer 30 and a gate structure containing a conductive gate 40 with a gate insulator 35 has been formed in the trench and is connected to gate 45. Heavily doped p-type well regions 50 have been formed in an upper portion of the epitaxial layer. Heavily doped n-type source regions 55 have been formed near the upper surface of the epitaxial layer. A source metal layer 60 has been formed on the upper surface of structure and is connected to source 65. In the UMOS structure 10, the source and optionally the well regions have been formed prior to forming the trench and the gate structures, as described below.

The methods for making these UMOS structures begin in some embodiments, as depicted in FIG. 2, when a semiconductor substrate 105 is first provided. Any substrate known in the art can be used in the invention. Suitable substrates include silicon wafers, epitaxial Si layers, bonded wafers such as used in silicon-on-insulator (SOI) technologies, and/or amorphous silicon layers, all of which may be doped or undoped. Also, any other semiconducting material used for electronic devices can be used, including Ge, SiGe, SiC, GaN, GaAs, InₓGa_{y}As_{z}, AlₓGa_{y}As_{z}, and/or any pure or compound semiconductors, such as III-V or II-VIs and their variants. In some embodiments, the substrate 105 can be heavily doped with any n-type dopant.

The substrate 105 can contain one or more epitaxial (“epi”) Si layers located on an upper surface of the substrate 105. In the embodiments shown in FIG. 2, the epitaxial layer(s) comprises a first epitaxial layer 110, a second epitaxial layer 120, and a third epitaxial layer 130. The first epitaxial layer 110 can be provided using any known process in the art, including any known epitaxial deposition process. The epitaxial layer 110 can be lightly doped with an n-type dopant using any process known in the art.

The second epitaxial layer 120 will be used to form the well regions in the UMOS devices. The second epitaxial layer 120 can be provided using any known process in the art, including any known epitaxial deposition process using a temperature ranging from about 900° C. to about 100° C. The second epitaxial layer 120 can be heavily doped with a p-type dopant using any process known in the art. In some configurations, the second epitaxial layer 120 can be in-situ doped while being deposited to a dopant concentration ranging from about 1×10¹⁷ to about 3×10¹⁷ atoms/cm³. In other configurations, the second epitaxial layer 120 can be doped to concentration of about 2×10¹⁷ atoms/cm³ using B atoms.

The third epitaxial layer 130 will be used to form the source regions in the UMOS devices. The third epitaxial layer 130 can be provided using any known process in the art, including any known epitaxial deposition process at temperature ranging from about 900° C. to about 1000° C. The third epitaxial layer 130 can be heavily doped with an n-type dopant using any process known in the art. In some configurations, the third epitaxial layer 130 can be in-situ doped while being deposited to a dopant concentration ranging from about 7×10¹⁸ to about 2×10¹⁹ atoms/cm³. In other configurations, the third epitaxial layer 130 can be doped to concentration of about 1×10²⁰ atoms/cm³ using P atoms. Since the dopants in the second and third epitaxial layers can be formed using an in-situ process, there is no implant process and no high temperature activation or drive-in process that is needed to form these layers.

In some configurations, the dopant concentration in the third epitaxial layer 120 might need to be increased to reach the concentration of 1×10²⁰ atoms/cm³. In these configurations, a shallow source implant process as known in the art can be used to increase the dopant concentration in this third epitaxial layer 130. In some instances, a shallow source implant of As and/or P atoms at energies ranging from about 10 to about 100 KEV could be used to increase the source concentration to 1×10²⁰ atoms/cm³.

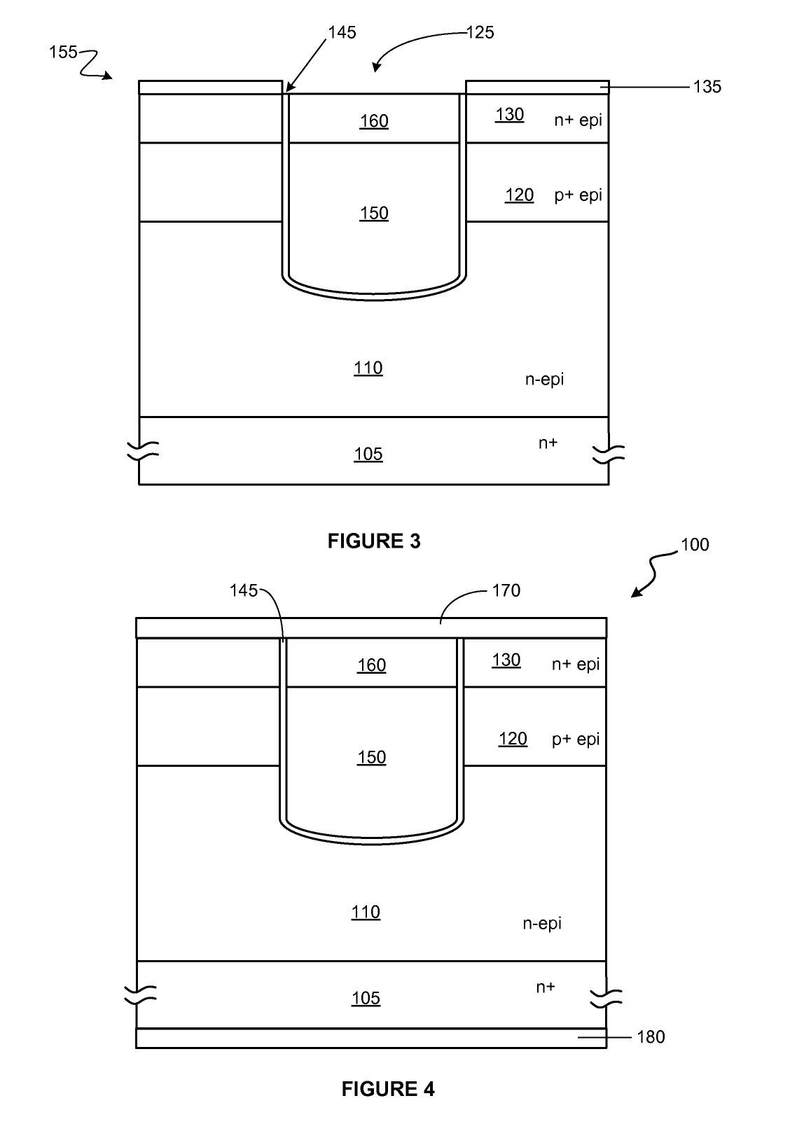

After the second and third epitaxial layers have been formed, a trench structure 125 can be formed. The bottom of the trench 125 can reach anywhere into epitaxial layer 110, as shown in FIG. 3, or even into the substrate 105. The trench structure 125 can be formed by any known process. In some embodiments, a mask 135 can be formed on the upper surface of the third epitaxial layer 130 by first depositing a layer of the desired mask material and then patterning it using photolithography and etch process so the desired pattern for the mask 135 is formed. After an etching process used to create the trench 125 is complete, a mesa structure 155 has been formed between adjacent trenches 125. The etching process used to form the trench 125 can be performed until the trench 125 has reached the desired depth and width in the epitaxial layers. The depth and width of the trench 125, as well as the aspect ratio of the width to the depth, can be controlled so that so a later deposited oxide layer properly fills in the trench and avoids the formation of voids in the trench.

As shown in FIG. 3, a gate insulating layer 145 (or other semi-insulating material) can then be formed in the trenches 125. In some embodiments, the gate insulating layer comprises a gate oxide layer 145. The gate oxide layer 145 can be formed by any process known in the art. In some embodiments, the gate oxide layer 145 can be formed by any deposition and etch process known in the art. In other embodiments, the gate oxide layer 145 can be formed by oxidizing the trench 125 in an oxide-containing atmosphere until the desired thickness of the gate oxide layer 145 has been grown.

Subsequently, a conductive layer can be deposited on the gate oxide layer 145. The conductive layer can comprise any conductive and/or semiconductive material known in the art including any metal, silicide such as CoSi₂, doped or undoped polysilicon, or combinations thereof. The conductive layer can be deposited by any known deposition process, including chemical vapor deposition processes (CVD, PECVD, LPCVD) or sputtering processes using the desired metal as the sputtering target.

The conductive layer can be deposited so that it fills and overflows over the trench 125. Then, a gate conductor 150 can be formed from the conductive layer using any process known in the art. In some embodiments, the gate conductor 150 can be formed by removing the upper portion of the conductive layer using any process known the art, including any etchback process. The result of the removal process leaves a conductive layer (the gate conductor 150) on the gate oxide layer 145 in the trench 125, as shown in FIG. 3. In some configurations, the gate conductor 150 can be formed so that its upper surface is substantially planar with the upper surface of the epitaxial layer 120, as shown in FIG. 3. In other configurations, the gate conductor 150 can be formed so that its upper surface is not substantially planar with the upper surface of the epitaxial layer 120

In some configurations, the upper surface of the gate conductor 150 can be covered with an overlying insulating layer. The overlying insulating layer can be any insulating material known in the art. In some embodiments, the overlying insulating layer comprises any dielectric material containing B and/or P, including BPSG, PSG, or BSG materials. In some embodiments, the overlying insulating layer may be deposited using any CVD process until the desired thickness is obtained. Examples of the CVD processes include PECVD, APCVD, SACVD, LPCVD, HDPCVD, or combinations thereof. When BPSG, PSG, or BSG materials are used in the overlying insulating layer, they can be reflowed.

In these configurations, a portion of the overlying insulating layer is removed to leave an insulation cap. In the embodiments depicted in FIG. 3, the unwanted portions of the overlying insulating layer can be removed using any known mask and etching procedure that removes the materials in locations other than the gate conductor 150. Thus, an insulating cap 160 is formed over the gate conductor 150. In the embodiments depicted in FIG. 3, the overlying insulating layer can be removed using any etch back or planarization process so that an insulator cap 160 is formed with an upper surface substantially planar with the third epitaxial layer 130.

Next, as shown in FIG. 4, a source layer 170 can be deposited over the upper portions of the insulation cap 160 and the epitaxial layer 130. The source layer 170 can comprise any conductive and/or semiconductive material known in the art, including any metal, silicide, polysilicon, or combinations thereof. The source layer 170 can be deposited by any known deposition process, including chemical vapor deposition processes (CVD, PECVD, LPCVD) or sputtering processes using the desired metal as the sputtering target.

After (or before) the source layer 170 has been formed, a drain layer 180 can be formed on the backside of the substrate 105 using any process known in the art. In some embodiments, the drain 180 can be formed on the backside by thinning the backside of the substrate 105 using any process known in the art, including a grinding, polishing, or etch processes. Then, a conductive layer can be deposited on the backside of the substrate 105 as known in the art until the desired thickness of the conductive layer of the drain is formed, as shown in FIG. 4.

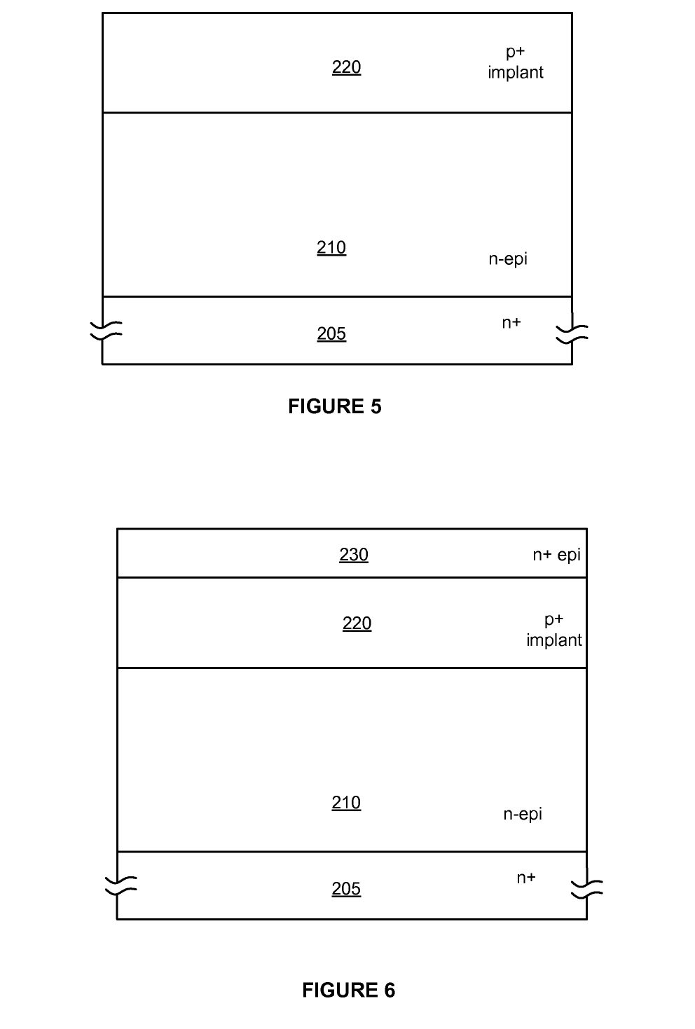

In other embodiments, the UMOS structures can be formed using different processing. In these embodiments, a first epitaxial layer 210 (on substrate 205) is formed similarly to the first epitaxial layer 110 described above, as shown in FIG. 5. The first epitaxial layer 210 is, however, grown thicker than the first epitaxial layer 110. An upper portion of the first epitaxial layer 210 is then implanted with a p-type dopant using any process known in the art until the desired dopant concentration is obtained. In some configurations, the dopants are implanted at a high energy ranging from about 100 KEV to about 200 KEV. In other configurations, the dopants are implanted at a high energy ranging from about 900 KEV to about 1 MEV.

The dopants are then activated using any process as known in the art to drive-in and activate the dopants. In some instances, the dopants can be activated using a furnace process at temperatures ranging from about 900° C. to about 1000° C. In other instances, the dopants can be activated using microwave heating at temperatures ranging from about 250 to about 550° C. In these embodiments, another epitaxial layer 230 is then formed which is similar to the third epitaxial layer 130, as shown in FIG. 6. Similar processing steps to those described above can then be performed to complete the UMOS structure.

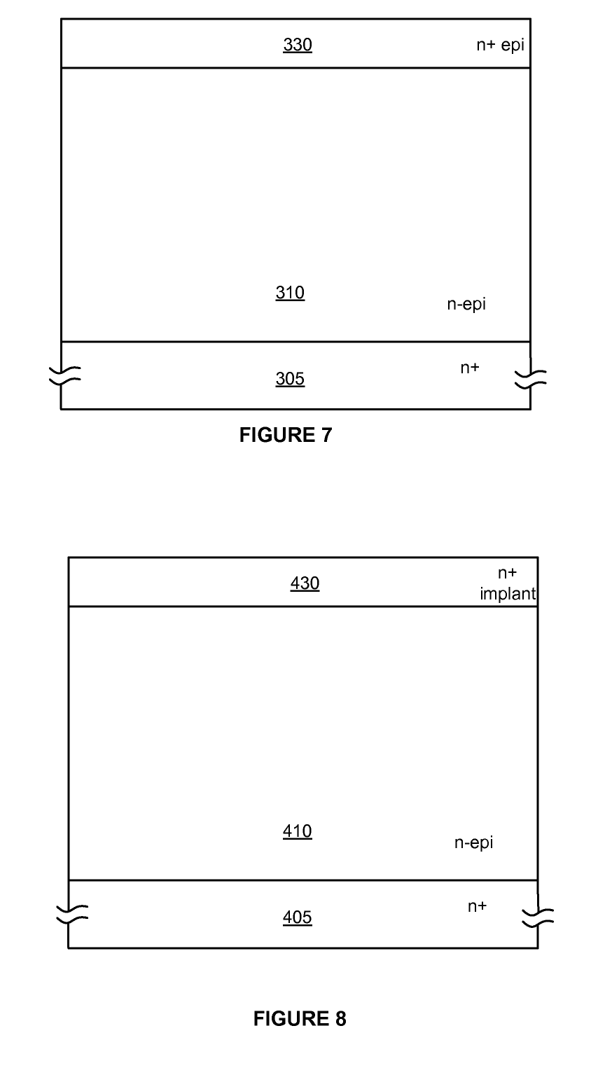

In yet other embodiments, the UMOS structures can be formed using other processes. In some configurations of these embodiments, a first epitaxial layer 310 (on substrate 305) is formed similarly to the first epitaxial layer 110 described above, as shown in FIG. 7. The first epitaxial layer 310 is, however, grown thicker than the first epitaxial layer 110. An epitaxial layer 330 is then formed which is similar to the third epitaxial layer 130. In other configurations of these embodiments, as shown in FIG. 8, a first epitaxial layer 410 (on substrate 405) can be grown to an even greater thickness than the first epitaxial layer 110. In these configurations, an upper portion of the first epitaxial layer 410 is then implanted with a n-type dopant at a low energy ranging from about 10 KEV to about 100 KEV until the desired dopant concentration is obtained, thereby forming a dopant layer 430. The dopants in the dopant region 430 are then activated using any process as known in the art. In some instances, the dopants can be activated using a furnace process at temperatures ranging from about 900° C. to about 1000° C. In other instances, the dopants can be activated using microwave heating at temperatures ranging from about 250 to about 550° C.

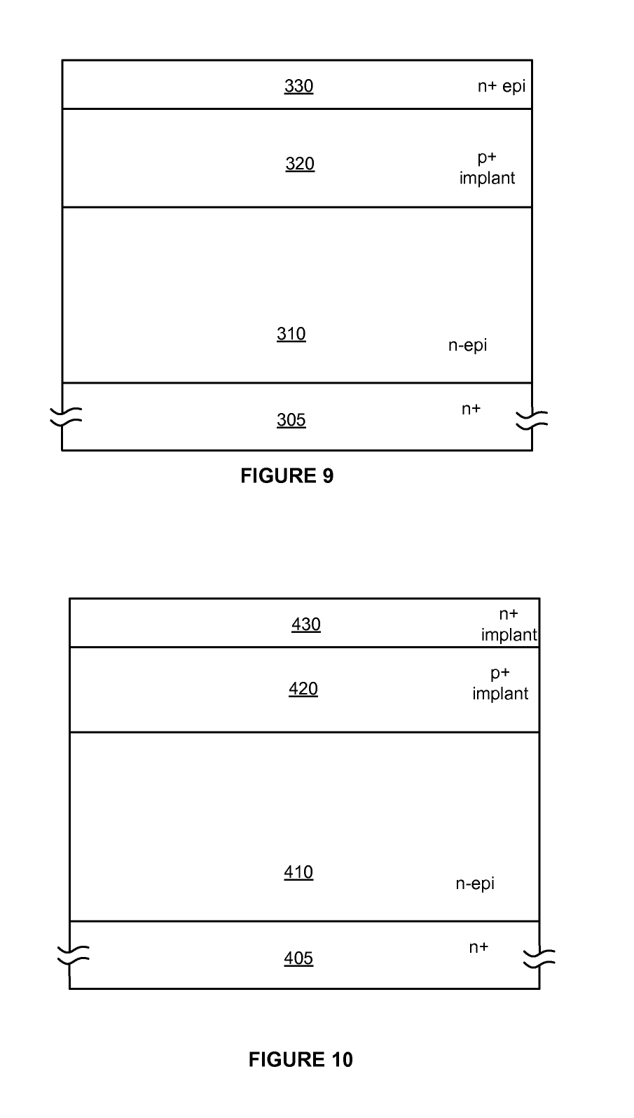

In both configurations of these embodiments (i.e., both FIGS. 7 and 8), a middle portion of the first epitaxial layer (whether 310 or 410) is then implanted with a p-type dopant at a high energy ranging from about 100 KEV to about 220 KEV until the desired dopant concentration is obtained, thereby forming dopant regions 320 or 420, as shown respectively in FIGS. 9 and 10. These dopants are then activated using any process as known in the art. In some instances, the dopants can be activated using a furnace process at temperatures ranging from about 900 C to about 1000° C. In other instances, the dopants can be activated using microwave heating at temperatures ranging from about 250 to about 550° C. In some instances, a single activation process can be used for both the source drive-in process and the well-drive in process. Similar processing steps to those described above can then be performed to complete the UMOS structure.

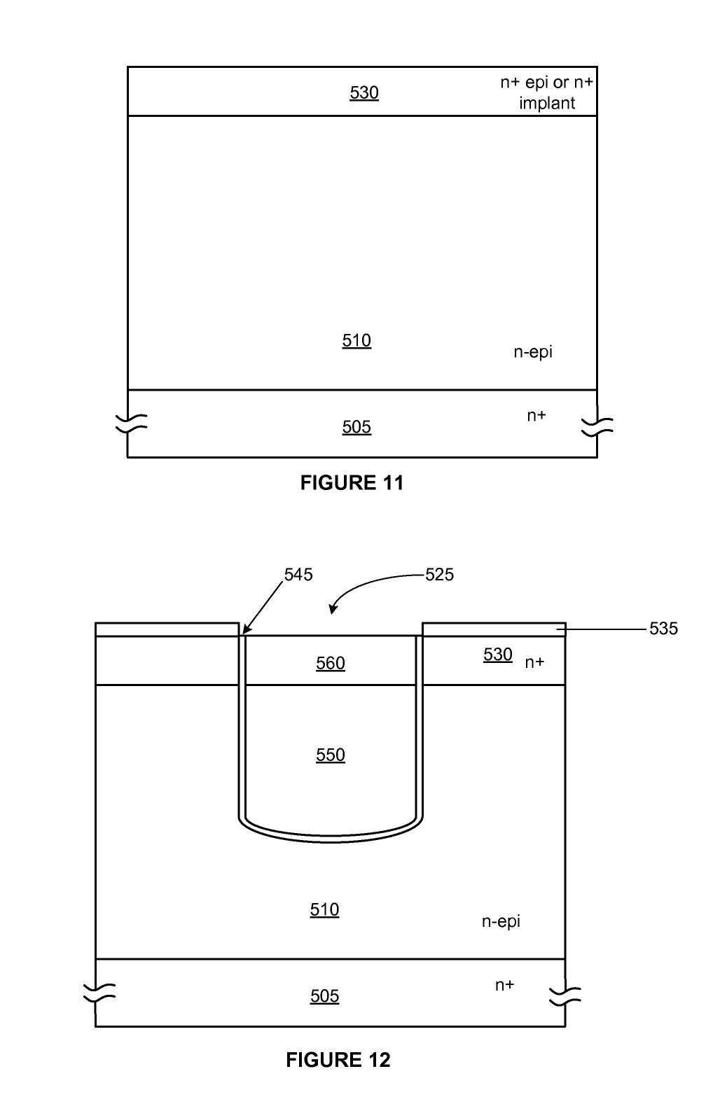

In yet other embodiments, the UMOS structures can be formed using yet other methods. In some configurations of these embodiments, a first epitaxial layer 510 (on substrate 505) is formed similarly to the first epitaxial layer 110 described above, as shown in FIG. 11. Another epitaxial layer 530 is then formed which is similar to the epitaxial layer 130. In other configurations, though, the first epitaxial layer 510 can be grown to an even greater thickness than the first epitaxial layer 110. In these configurations, an upper portion of the first epitaxial layer 510 is then implanted and activated with a n-type dopant similar to the implant process described above, thereby forming implant layer 530.

In these embodiments, a trench structure 525 can then be manufactured similar to the methods used to make the trench structure 125, as shown in FIG. 12. A gate oxide layer 545 can then be manufactured similar to the methods to make the gate oxide layer 145. A gate conductor 550 can then be manufactured similar to the methods to make the gate conductor 150. An insulation cap 560 can then be manufactured similar to the methods to make the insulation cap 160 described above.

Then, a middle portion of the epitaxial layer 510 can be implanted with a p-type dopant at a high energy ranging from about 100 KEV to about 220 KEV until the desired dopant concentration is obtained. These dopants are then activated using any process as known in the art to create a well region 520. In some instances, the dopants can be activated using a furnace process at temperatures ranging from about 900 to about 1000° C. In other instances, the dopants can be activated using microwave heating at temperatures ranging from about 250 to about 550° C. Similar processing steps to those described above are then performed to complete the UMOS structure.

These methods of manufacturing have several useful features. The processes form the source region of a UMOS semiconductor device before the etch processes that are used to create the trench. By forming the source region before the making the gate structure, the high temperatures processes (usually about 900° C. or 1000° C.) used for the source activation and drive in processes are no longer needed. Thus, low temperature materials which typically could not survive the high temperature of the activation and drive-in process can be used. Examples of these low temperature materials include silicides, such as CoSi2 or TiSi2, low-K gate dielectric materials such as Black Diamond™ or Coral™ materials, and spin on dielectric (SOG) materials.

These methods allow the source region to be produced by either an implant-and-drive process, an in-situ epitaxial process, or an epitaxial process with a shallow implant to increase the surface doping. Thus, for low voltage devices, the trenches could be used to isolate the source region in the mesas area from active devices. As well, a tighter dopant profile control for the source region can be obtained in those configurations where it is loosened by subsequent oxidation steps. The well implant processes can also be performed before or after the source or after the gate has been formed in the trench.

These methods also can reduce or eliminate the auto doping that occurs during high temperatures source activation and drive-in. This auto doping occurs when the silicon material in the source region is exposed to etched dielectrics that contain B and P.

These methods can also improve the threshold voltage (Vt) control by reducing or eliminating the dopant in the source region from scattering laterally into the channel region through the gate sidewall. This lateral doping can occur in the recess above the gate structure when doping the source region after the gate conductor has been formed.

These methods also can allow better control of the dopant profiles of source and well by reducing the thermal budget that is needed for source and well formation with use of low temperature gate oxidation processes.

These methods can also allow enhanced oxidation of the mesa region between the trenches by As dopants without oxidizing the gate material, as is often done in current well drive-in process. The enhanced oxidation allows protection of the source region from the heavy body etch that is used on the thick oxide layers that often cover the source region.

These methods can also eliminate or reduce the void creation and migration to the gate oxide layer from amorphous Si or polysilicon Si gates. During the high temperatures encountered during source activation and drive-in after the gate formation, the grains of the amorphous Si or polycrystalline Si can move and create voids in the gate conductor material.

It is understood that all material types provided herein are for illustrative purposes only. Accordingly, one or more of the various dielectric layers in the embodiments described herein may comprise low-k or high-k dielectric materials. As well, while specific dopants are names for the n-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (N or P, respectively) by appropriate modifications.

In some embodiments, a method for making a semiconductor device comprises providing a semiconductor substrate heavily doped with a dopant of a first conductivity type; providing an epitaxial layer on the substrate, the epitaxial layer being lightly doped with a dopant of the first conductivity type; providing a trench formed in the epitaxial layer, the trench containing both a gate insulting layer comprising a low temperature dielectric material and a gate conductor comprising a low temperature conductive material; providing a well region heavily doped with a dopant of a second conductivity type; and providing a source region heavily doped with a dopant of the first conductivity type.

In some embodiments, a method for making a semiconductor device comprises heavily doping a semiconductor substrate with a dopant of a first conductivity type; forming a first epitaxial layer on the substrate, the epitaxial layer being lightly doped with a dopant of the first conductivity type; forming a source region heavily doped with a dopant of the first conductivity type by growing a second epitaxial layer with such a dopant concentration or by implanting an upper portion of the first epitaxial layer with a dopant of the first conductivity type and then activating that dopant to obtain that dopant concentration; forming a trench in the epitaxial layer; forming a gate insulating layer on the bottom and sidewall of the trench, the gate insulating layer comprising a low temperature insulating material; and forming a gate conductor comprising a low temperature conductive material on the gate insulating layer.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1-24. (canceled)

25. A method for making a semiconductor device, comprising:
providing a semiconductor substrate heavily doped with a dopant of a first conductivity type;
providing an epitaxial layer on the substrate, the epitaxial layer being lightly doped with a dopant of the first conductivity type;
providing a trench formed in the epitaxial layer, the trench containing both a gate insulating layer comprising a low temperature dielectric material and a gate conductor comprising a low temperature conductive material;
providing a well region heavily doped with a dopant of a second conductivity type; and
providing a source region heavily doped with a dopant of the first conductivity type.

26. The method of claim 25, wherein the first conductivity type dopant is an n-type dopant and the second conductivity type dopant is a p-type dopant.

27. The method of claim 25, further comprising providing a conductive source layer contacting the source region and a conductive drain layer contacting a bottom portion of the substrate.

28. The method of claim 25, wherein the low temperature dielectric material used in the gate insulating layer comprises a SOG material, a low-K dielectic material, or a combination thereof.

29. The method of claim 28, wherein the low temperature dielectric material comprises a low-K dielectic material.

30. The method of claim 25, wherein the low temperature conductive material used in the gate conductor comprises a metal silicide.

31. The method of claim 25, wherein the low temperature conductive material comprises TiSi₂, CoSi₂, or a combination thereof.

32. The method of claim 25, wherein the low temperature conductive material comprises CoSi₂.

33. The method of claim 25, wherein the low temperature dielectric material is formed at a temperature less than about 900° C. and the low temperature conductive material is formed at a temperature less than about 900° C.

34. The method of claim 25, wherein the source region is formed prior to forming the trench.

35. A method for making a UMOS semiconductor device, comprising:
heavily doping a semiconductor substrate with a dopant of a first conductivity type;
forming a first epitaxial layer on the substrate, the epitaxial layer being lightly doped with a dopant of the first conductivity type;
forming a source region heavily doped with a dopant of the first conductivity type by growing a second epitaxial layer with the desired dopant concentration or by implanting an upper portion of the first epitaxial layer with a dopant of the first conductivity type and then activating that dopant to obtain the desired dopant concentration;
forming a trench in the epitaxial layer;
forming a gate insulating layer on the bottom and sidewall of the trench, the gate insulating layer comprising a low temperature insulating material; and
forming a gate conductor comprising a low temperature conductive material on the gate insulating layer.

36. The method of claim 35, wherein the first conductivity type dopant is an n-type dopant and the second conductivity type dopant is a p-type dopant.

37. The method of claim 35, further comprising providing a conductive source layer contacting the source region and a conductive drain layer contacting a bottom portion of the substrate.

38. The method of claim 35, wherein the low temperature dielectric material used in the gate insulating layer comprises a SOG material, a low-K dielectic material, or a combination thereof.

39. The method of claim 38, wherein the low temperature dielectric material comprises a low-K dielectic material.

40. The method of claim 35, wherein the low temperature conductive material used in the gate conductor comprises a metal silicide.

41. The method of claim 35, wherein the low temperature conductive material comprises TiSi₂, CoSi₂, or a combination thereof.

42. The method of claim 35, wherein the low temperature conductive material comprises CoSi₂.

43. The method of claim 35, further comprising forming the low temperature dielectric material at a temperature less than about 900° C. and forming the low temperature conductive material at a temperature less than about 900° C.
